(19) United States
(12) Patent Application Publication
(10) Pub. No.: US 2004/0251919 A1
(43) Pub. Date: Dec. 16, 2004

(54) Method of measuring the concentration of a fluid component that has a variable dielectric characteristic

(75) Inventors: Daniel Stahlmann, Williamsburg, VA (US); Isabelle McKenzie, Poquoson, VA (US); Ray Wildeson, Yorktown, VA (US); Daniel L. Childs, Williamsburg, VA (US)

Correspondence Address: SIEMENS CORPORATION, INTELLECTUAL PROPERTY LAW DEPARTMENT, 170 WOOD AVENUE SOUTH, ISELIN, NJ, 08830, US

(73) Assignee: Siemens VDO Automotive Corporation, Auburn Hills, MI

(21) Appl. No.: 10/869,137

(22) Filed: Jun. 16, 2004

Related U.S. Application Data
(60) Provisional application No. 60/478,755, filed on Jun. 16, 2003.

(51) Int. Cl. G01R 27/26

(52) U.S. Cl. 324/663; 324/674

(57) ABSTRACT

A method of determining the concentration of a component of interest within a fluid (22) within a container (24) includes determining a permittivity of the fluid, determining a conductivity of the fluid and determining the concentration of the component of interest based on a direct relationship between the determined permittivity and the determined conductivity. An example sensor for making such a concentration determination includes a capacitor portion (26) and control electronics (30) that operate the capacitor in a first mode for making the permittivity determination and a second mode for making the conductivity determination. An example data set (32) includes at least one three dimensional polynomial that describes a relationship between permittivity, conductivity and temperature for a particular concentration value. A disclosed example is well suited for making urea concentration level determinations.

### CROSS REFERENCE TO RELATED APPLICATIONS

This application claims priority to U.S. Provisional Patent Application No. 60/478,755, which was filed on Jun. 16, 2003.

### FIELD OF THE INVENTION

This invention generally relates to determining a property of a fluid. More particularly, this invention relates to determining the concentration of a component in a fluid where the component has a dielectric characteristic that is not constant.

### DESCRIPTION OF THE RELATED ART

There are a variety of situations where determining a concentration level of one or more components in a fluid mixture is useful or necessary. One example is in automotive fuel systems. It is useful, for example, to determine the alcohol content within a fuel mixture for purposes of adjusting fuel supply parameters in fuel injection systems. A known technique for making such a determination is shown in U.S. Pat. No. 5,367,264. That document discloses a way of determining the alcohol content of a fuel mixture based on a capacitance and conductance of a capacitor-based measuring circuit, which is exposed to the fuel mixture. A variety of such devices are known.

One limitation of such devices is that they are only useful for fluids of limited conductivity. Fluids having relatively higher conductivity present special challenges that render most capacitor-based concentration measuring devices unreliable or ineffective. There is a need for a reliable technique for determining the contents of higher conductivity fluids.

One example situation where such a technique is desirable is determining a urea concentration level in a fluid supplied to a catalytic converter that uses a known selective catalytic reaction (SCR) to control vehicle engine emissions. Such devices utilize a mixture of urea and de-ionized water for producing ammonia hydroxide, which is used to control the nitrogen oxide in exhaust emissions. Typical arrangements include a supply tank that must be periodically filled by a vehicle owner or operator. In one example, an operator of a heavy vehicle (i.e., a large truck) must deposit urea into a supply tank much like depositing fuel into a fuel tank.

The possibility exists that a vehicle operator will inadvertently or intentionally not place an appropriate amount of urea into the appropriate supply tank. If there is an insufficient amount of urea within the mixture, for example, the catalytic converter will not be able to perform as desired. It is therefore desirable to be able to provide an indication of a urea concentration level so that a vehicle operator may be alerted to the need to make an adjustment or correction. It is also desirable to be able to automate a supply rate of the mixture into the catalytic converter to compensate for varying urea concentration levels.

There has been no commercially available device that is capable of providing a reliable urea concentration determination that would be useful for such situations. Urea has properties that tend to interfere with the possibility of making a reliable measurement. For example, it appears that urea does not have a fixed dielectric constant. The dielectric characteristic of urea varies with temperature and depends on the chemical reactions within urea, which involve varying amounts of ammonia hydroxide. The amount of ammonia hydroxide also varies with temperature and time. As urea becomes warmer, older or both, the amount of ammonia hydroxide increases, which affects conductivity and further complicates determining a value of the dielectric characteristic of urea.

There is a need for a technique and device for determining concentration levels of components within fluids that are not discernable using known sensors that rely upon a dielectric constant for determining the contents of a fluid mixture. This invention addresses that need.

### SUMMARY OF THE INVENTION

An exemplary disclosed method of determining the concentration of a component within a fluid includes determining a permittivity of the fluid and a conductivity of the fluid. Determining a relationship between the determined permittivity and the determined conductivity provides an indication of the concentration.

The example method allows for determining a concentration of a component that has a dielectric characteristic that is not constant. The disclosed method allows for determining the concentration of a component that has a dielectric characteristic that varies with the conductivity. Determining a direct relationship between the determined permittivity and the determined conductivity provides information about the dielectric characteristic, which provides an indication of the concentration of the component.

Urea is one example component of interest that has a dielectric characteristic that varies with conductivity and temperature. One example method includes determining a relationship between the determined permittivity, conductivity and the temperature of the fluid.

In one example, a data set for a plurality of known concentrations is determined that defines the relationship between at least permittivity and conductivity for each of the concentrations. Determining how the determined permittivity and the determined conductivity correspond to the data set provides an indication of the concentration. In one example, the data set includes a three dimensional polynomial that corresponds to the relationship between permittivity, conductivity and temperature for a concentration.

An example device for determining the concentration of a component in a fluid includes a capacitor that is adapted to be exposed to the fluid such that the fluid builds a dielectric between a cathode and an anode of the capacitor. A controller determines the permittivity of the fluid based on the capacitor operating in a first mode. The controller also determines conductivity based on the capacitor operating in a second mode. The controller then uses the determined permittivity and the determined conductivity to determine the concentration of the component. In one example, the dielectric characteristic of the component also varies with temperature and the controller either makes the determinations at a known temperature or determines the temperature within a chosen range when determining the permittivity and the conductivity.

The various features and advantages of this invention will become apparent to those skilled in the art from the following detailed description of a currently preferred embodiment. The drawings that accompany the detailed description can be briefly described as follows.

### BRIEF DESCRIPTION OF THE DRAWINGS

FIG. 1 schematically illustrates a sensor device designed according to an example embodiment of this invention.

FIG. 2 graphically illustrates an example data set useful with the embodiment of FIG. 1.

FIG. 3 schematically illustrates, in somewhat more detail, selected control electronics of the embodiment of FIG. 1.

FIG. 4 schematically illustrates further details of example control electronics useful with the embodiment of FIG. 1.

FIG. 5 graphically illustrates an output signal technique useful with the embodiment of FIG. 1.

FIG. 6 graphically illustrates an alternative output signaling technique useful with the embodiment of FIG. 1.

### DETAILED DESCRIPTION OF THE PREFERRED EMBODIMENT

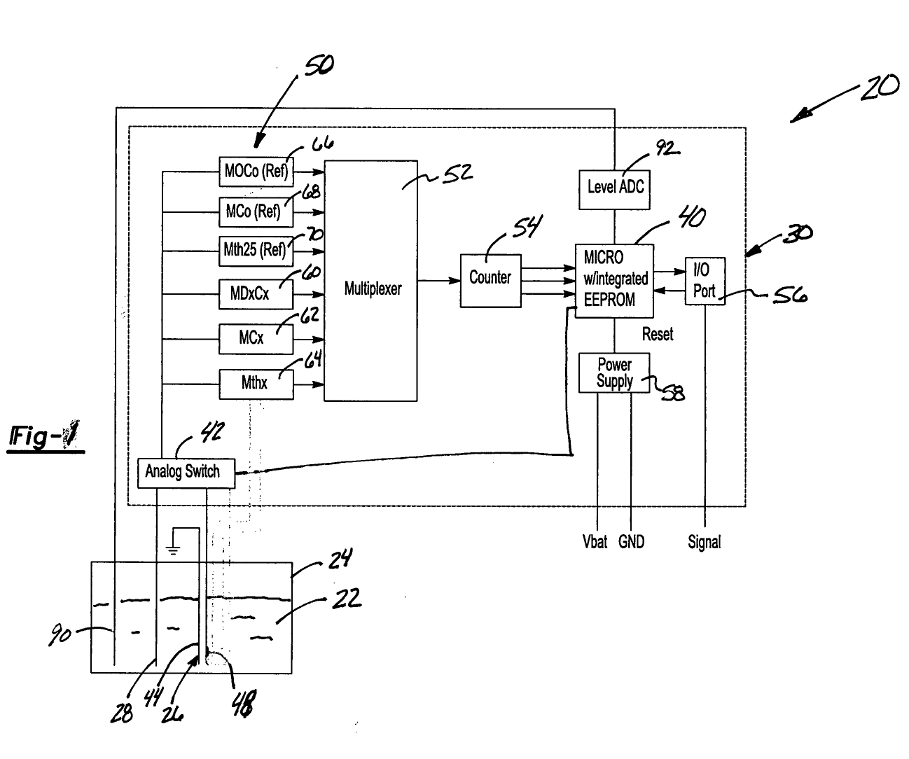

FIG. 1 schematically shows a sensor device 20 that is useful for determining the concentration of a component of interest within a fluid 22 in a container 24. The example sensor device 20 includes a capacitor portion 26 that is adapted to be exposed to the fluid 22. A temperature sensor portion 28 provides information regarding the temperature of the fluid 22. Control electronics 30 cause selective operation of the capacitor portion 26 and the temperature sensor portion 28 to make a determination regarding the concentration of the component of interest.

One example use of the sensor device 20 is for determining the concentration of a fluid component that has a dielectric characteristic that is not constant. Many substances or materials have a dielectric constant. Others, however, have a dielectric characteristic or property that is not constant. One example is urea. The dielectric characteristic of urea varies as mentioned above. It is therefore, not possible to use known sensors or techniques that rely upon a substance of interest having a dielectric constant in situations where the substance of interest has a variable dielectric characteristic.

An example device has a capacitor portion 26 that has an active surface ratio between a cathode and an anode that is sufficient enough to compensate for high conductivity on the one hand yet leaves enough resolution to make a dielectric measurement. Given this description, those skilled in the art will be able to select an appropriate ratio to meet the needs of their particular situation.

With the example of FIG. 1, the capacitor portion 26 selectively operates in a first mode to provide a measurement of the permittivity of the fluid 22. The capacitor portion 26 also operates in a second mode to provide a measurement of the conductivity of the fluid 22. The control electronics 30 determine a relationship between the permittivity and the conductivity to make a determination regarding the concentration of the component of interest.

In situations where the temperature of the fluid 22 will vary, the temperature sensor portion 28 provides an indication of temperature so that a concentration determination can be made even when the substance of interest has a dielectric characteristic that varies with temperature. In one example, the temperature of the fluid 22 is assumed to be a specific value or within a given range of temperatures and the control electronics 30 use the permittivity and conductivity determinations for determining the concentration level. In another example, the control electronics 30 use an indication from the temperature sensor portion 28 along with the determined permittivity and conductivity for making the concentration determination.

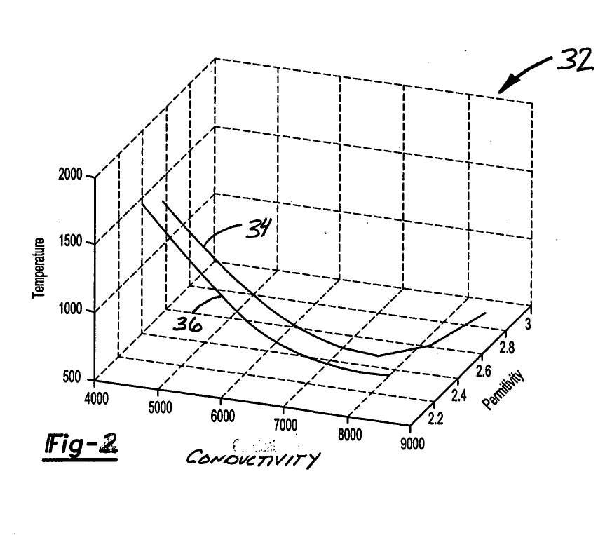

The control electronics 30 in this example include a memory portion having a data set that represents the relationship between permittivity and conductivity corresponding to a plurality of concentration values. FIG. 2 graphically illustrates one example data set 32. In this example, a three dimension polynomial corresponds to the relationship between conductivity, permittivity and temperature for a particular concentration level. The illustrated example shows example data polynomials for urea concentrations at 34 and 36. In this example, the plot 34 represents a 30% urea concentration level while the plot 36 represents a 20% urea concentration level.

In one example, known concentration levels are sampled at different temperatures and different conductivity levels to obtain the data indicating the relationship between permittivity and conductivity for particular concentrations. By predetermining these relationships and storing them in an appropriate data set format, the control electronics 30 can utilize the measured or determined permittivity and conductivity to then make a determination regarding the concentration of the component of interest.

In one example, the temperature of the fluid is assumed to remain constant or within a selected range and the data set includes a two dimensional polynomial defining the relationship between permittivity and conductivity. The particular format of the data set defining the relationships between permittivity and conductivity for various concentration levels can be customized to suit the needs of a particular situation. Those skilled in the art who have the benefit of this description will be able to configure a data set to meet their particular needs.

Returning to FIG. 1, the control electronics 30 in this example includes a controller 40, such as a microprocessor, that contains the memory including the data set 32. In one example, the controller 40 comprises a commercially available Motorola chip having the designation MC681HC908AZ60A.

The controller 40 controls a switch 42 for selectively operating the capacitor portion 26 and the temperature sensor portion 28. One advantage to the example embodiment is that a single connection between the capacitor portion 26 and the control electronics 30 (i.e., the switch 42) can be used while still operating the capacitor portion 26 in a first mode to make a permittivity determination and a second mode to make a conductivity determination.

Once the controller 40 makes the concentration determination, an output signal from an input/output port 56 provides concentration level information to be used according to the requirements of a particular situation.

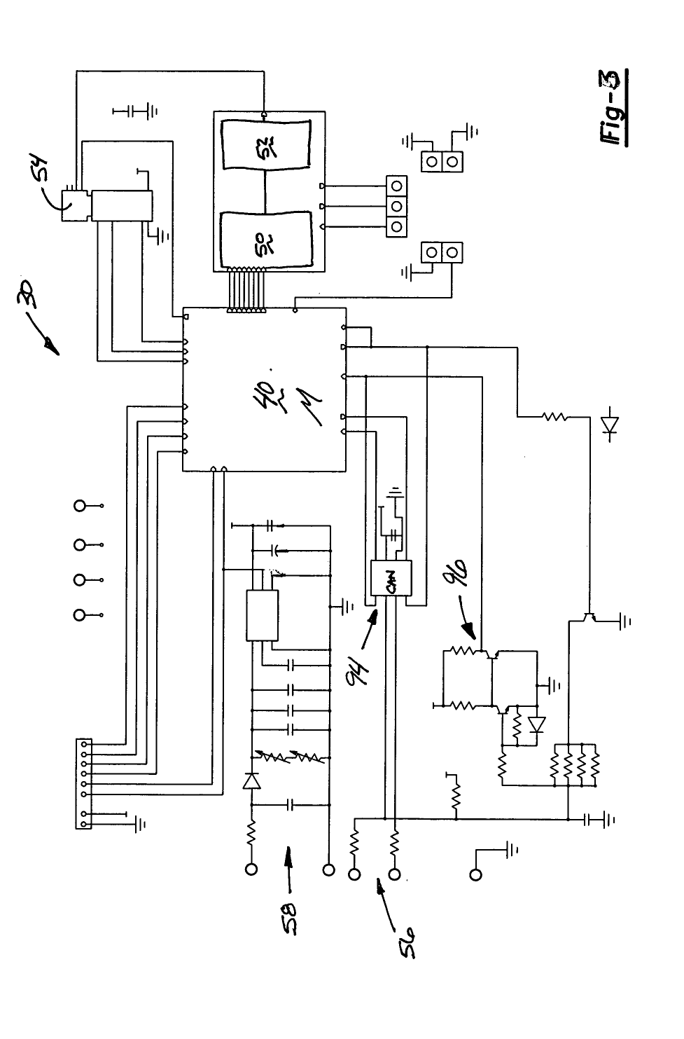

A power supply portion 58 includes a voltage regulator, for example, for supplying power to the controller 40 and the other portions of the control electronics 30 for appropriately operating the capacitor portion 26 and the temperature sensor portion 28, for example. FIG. 3 shows portions of the control electronics 30 in one particular embodiment.

In this example, the capacitor portion 26 has a cathode 44 and an anode 48 that are both at least partially submerged in the fluid 22. The fluid between the cathode 44 and the anode 48 effectively completes the circuit between them and allows for making a permittivity and conductivity measurement of the fluid 22.

In the illustrated example, a plurality of oscillators 50 are provided for making the measurements used to determine the concentration level of interest. The capacitor 26 operates in a first mode to make a permittivity determination. A first oscillator 60 is selectively switched through the analog switch 42 to energize the capacitor portion 26 at a first frequency for making a permittivity determination.

A second oscillator 62 is switched through the switch 42 to be coupled with the capacitor portion 26 to operate the capacitor at a second, lower frequency for making a conductivity determination. A third oscillator 64 is selectively used to operate the temperature sensor portion 28. In one example, the temperature sensor portion 28 comprises a thermistor or a known NTC device. The output signals as a result of coupling the oscillators to the capacitor portion 26 or the temperature sensor portion 28 are processed through a multiplexer 52 and a counter 54 before they are provided to the controller 40.

In this example, a reference oscillator 66 provides a measurement of a reference point with zero conductivity. Another reference oscillator 68 provides a reference signal for compensating for temperature drift and aging influence on the oscillator components. Since the reference oscillator 68 is exposed to the same temperatures and undergoes the same aging as the other oscillators, the output from the reference oscillator 68 provides the ability to compensate for changes in oscillator performance associated with temperatures and aging of the components.

A third reference oscillator 70 is included in the illustrated example. The reference oscillator 70 provides a reference value for temperature measurements. In this example, the reference oscillator 70 provides a measured value at 25° C. for calibrating the oscillator 64.

The controller 40 utilizes the values provided by operation of the various oscillators 50 to automatically make the concentration level determination based upon a relationship between the determined permittivity and the determined conductivity. In one example, the controller 40 utilizes the raw measurement data regarding the permittivity and conductivity, correlates that raw measurement data to information based upon operating the reference oscillators and compensates for aging drift and temperature effects on the oscillators.

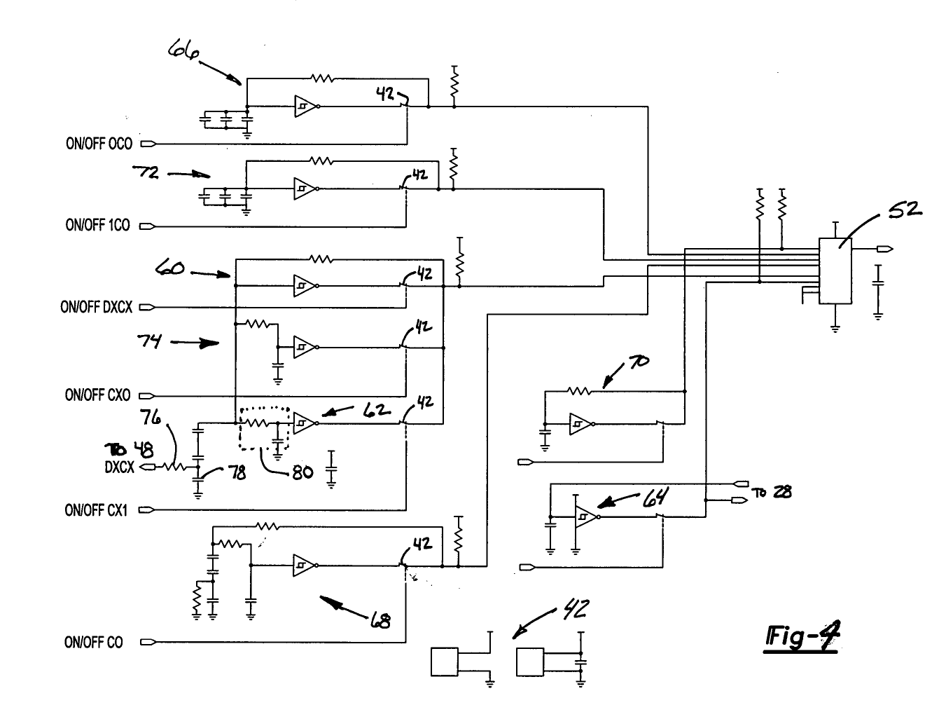

FIG. 4 schematically shows one example embodiment of the oscillators 50. In this example, some redundant oscillators 72 and 74 are included for back-up purposes or for additional references as may be desired.

The illustrated embodiment includes a pull up resistor 76 and a pull up capacitor 78 associated with the first oscillator 60 for making the permittivity determination. In this example, the pull up resistor 76 and the capacitor 78 provide the range needed for the ratio between capacitance and resistance to obtain measurement values even when the conductivity of the fluid 22 is relatively low. One example embodiment includes using LVC technology and the pull up values of the resistor 76 and capacitor 78 provide the quick time constant that allows using the LVC technology. The relatively high frequencies used during the measurements, especially that of permittivity, makes LVC technology a useful approach with the illustrated embodiment.

Another feature of the embodiment shown in FIG. 4 is a low pass filter 80 associated with the second oscillator 62 used for the conductivity measurement. The low pass filter 80 effectively filters out any high frequency components of the capacitor operation to provide a conductivity measurement.

The frequencies at which the various oscillators operate can be selected to meet the needs of a particular situation. In one example, the first oscillator 60 used for determining permittivity operates at 10 MHz, the second oscillator 62 used for determining conductivity operates at 20 KHz and the third oscillator 64 used for determining temperature operates within a range from 500 Hz to 1 MHz. In one example, the reference oscillator 66 operates at 10 MHz and the temperature reference oscillator 70 operates at 20 KHz. Those skilled in the art who have the benefit of this description will be able to select appropriate oscillator frequencies and values for the various components schematically shown in FIG. 4 to meet the needs of their particular situation.

Referring again to FIG. 1, the example sensor device 20 includes the ability to provide a level measurement regarding the level of fluid 22 within the container 24. In this example, a level probe potion 90 includes at least one electrode that is exposed to the fluid for making a level measurement. The control electronics 30 includes a level sensing driver portion 92 that operates the level probe portion 90 for making a level determination. In one example, a resistance value of the level probe portion 90 provides an indication of the level of fluid 22 within the container 24. One example operates according to the principles described in the published Application No. WO 0227280. The teachings of that document are incorporated into this description by reference. In one example, the level probe portion 90 includes two electrodes. In another example, one electrode is provided and the cathode 44 of the capacitor portion 26 operates as the other electrode.

Referring again to FIG. 3, the output port 56 of the sensor device 20 in this example has two possible outputs. A first output uses the known CAN communication technique and, therefore, a CAN device 94 is included as part of the control electronics 30. Another example output is a pulse width modulation output available from a pulse width modulation portion 96 that operates in a generally known manner to provide signal pulses of a length that corresponds to the voltage magnitude of the signal outputs from the controller 40.

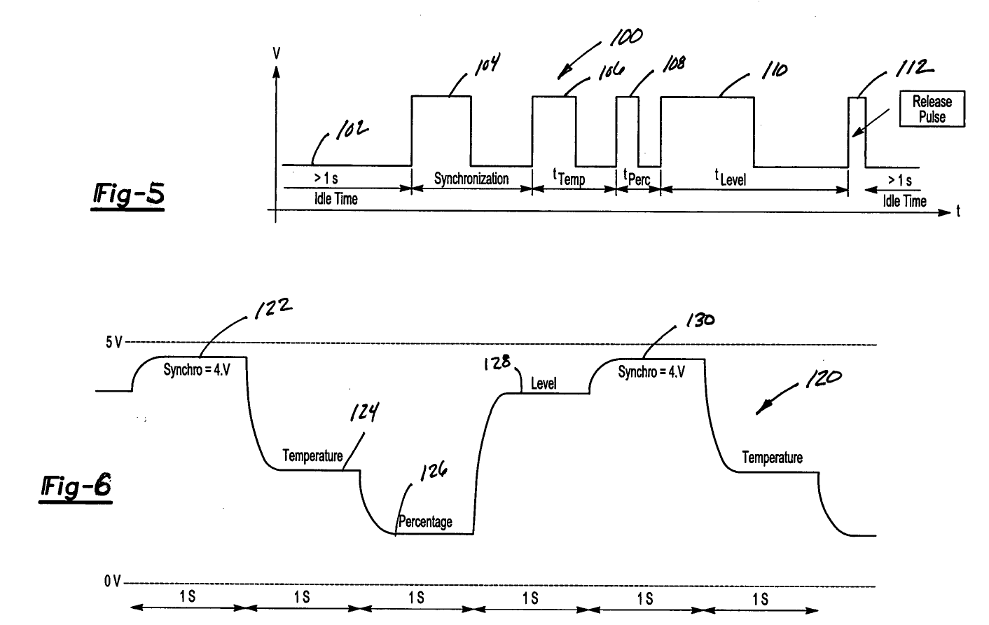

FIG. 5 shows one example output technique using the pulse width modulation portion 96. In this example, a pulse train 100 provides information regarding the various determinations made using the sensor device 20. In this example, the pulse train 100 includes an idle time 102 that precedes the measurement information from the pulse train 100. A first pulse 104 provides information to an outside device for synchronizing the devices in a manner that the substantive information following the synchronization pulse 104 will be properly received and interpreted. A pulse 106 provides information regarding the temperature determination. A subsequent pulse 108 provides information regarding the concentration level determination. Following that, a pulse 110 provides an indication of the determined level of fluid 22 within the container 24. A release pulse 112 signals the end of the pulse train and precedes another idle time 102.

In one example, the sizes or durations of the pulses 106, 108 and 110 are controlled within selected parameters to provide information in a predictable manner. One example technique includes providing information regarding contaminant detection, which is based at least in part upon a deviation from expected measurement values outside of a selected range.

In one example, the pulse train includes four pulse periods as illustrated in FIG. 5. In one example, the positive portion and negative portion of each pulse is equal so that the positive pulse, negative pulse or the whole pulse period can be used for interpreting the measured parameter values. The length of each positive pulse (and each negative pulse in an example where they are equal) is always at least 0.5 milliseconds in duration.

In one example the synchronization pulse has a length of ten milliseconds. The temperature pulse is between 1,000 and 15,500 microseconds. A 1,000 microsecond temperature pulse corresponds to a temperature reading of −40° C. Using a 100 microsecond per degree C. scale, a 15,500 microsecond pulse duration corresponds to a temperature reading of 105° C.

In one example, where there is an error in the temperature reading, the temperature pulse duration is 500 microseconds.

The concentration pulse in one example has a duration within a range from 2,000 microseconds to 10,000 microseconds. Using a scale of 200 microseconds per percentage unit, a 2,000 microsecond pulse duration corresponds to a 0% concentration determination. A 10,000 microsecond pulse duration corresponds to a 40% concentration determination.

In one example, the sensor device provides an indication regarding contamination of the fluid. One example embodiment includes providing a pulse that indicates contamination is present when the measured fluids do not match with preprogrammed data sets for a urea characteristic, for example. An expected range of urea concentration within the ionized water provides expected relationships between permittivity and conductivity. In this example, when the determined permittivity and conductivity do not have values corresponding to one of the expected relationships stored in the data set, that is used as an indication of contamination.

Given a lack of correspondence between the determined relationship and the expected relationships the conductivity measurement is used to provide an indication of contamination. In this example, the conductivity measurement is considered a measurement of the contaminant conductivity.

In one example, when the determined contaminant conductivity is less than 100 μS/cm, the output includes a fixed pulse duration of 12,000 microseconds in place of the concentration pulse. If the contaminant conductivity is determined to be within the range of 100 μS/cm to about 12,000 μS/cm, then the output pulse indicating contamination lasts 14,000 microseconds. In the event that the contaminant conductivity is greater than 12,000 μS/cm, the pulse has a fixed duration of 16,000 microseconds.

In the event that there is a sensor error regarding the concentration or contamination detection, the pulse length is 500 microseconds.

The level pulse in one example has a duration in the range from 1,000 microseconds to 11,000 microseconds. Using a 100 microsecond per percentage scale allows for a 1,000 microsecond pulse to indicate a 0% full level and an 11,000 microsecond to indicate a 100% full level. In the event that the level determination appears to be in error, the controller 40 provides a 500 microsecond level pulse duration.

FIG. 6 shows another example output technique where an analog signal 120 provides information regarding the various determinations made by the controller 40 regarding the fluid 22. In this example, the pulse width modulation portion 96 generates the analog output by switching between zero volts and five volts and having that switching smoothed with a low pass filter. In this example, the pulse with modulation period is set at 1000 microseconds, which allows a 0.1% resolution.

In the example of FIG. 6, a synchronization portion 122 of the signal 120 has a 4.7 volt magnitude. The synchronization portion 122 calibrates the analog levels and reduces any error linked to reference voltage tolerances. The next portion of the signal 120 shown at 124 has a voltage level that provides a temperature indication. The next portion 126 has a voltage level that provides an indication regarding the determined concentration level. Following that, a signal portion 128 has a voltage indicating the determined level of fluid 22 within the container 24. A next synchronization pulse 130 begins the sequence again.

The disclosed examples provide the ability to make a concentration determination regarding a component of interest even when the substance of the component does not have a dielectric constant. For substances such as urea that have a variable dielectric characteristic, the disclosed arrangement utilizes a relationship between a determined permittivity and conductivity of the fluid containing the component of interest to make a concentration level determination.

The preceding description is exemplary rather than limiting in nature. Variations and modifications to the disclosed examples may become apparent to those skilled in the art that do not necessarily depart from the essence of this invention. The scope of legal protection given to this invention can only be determined by studying the following claims.

We claim:

1. A method of determining the concentration of a component in a fluid, comprising the steps of:
determining a permittivity of the fluids;
determining a conductivity of the fluids; and
determining a concentration of the component based on a direct relationship between the determined permittivity and the determined conductivity.

2. The method of claim 1, including determining a temperature of the fluid and determining the concentration based on a relationship between the determined temperature, the determined permittivity and the determined conductivity.

3. The method of claim 2, including predetermining a plurality of three dimensional polynomials that are each indicative of a relationship between permittivity, conductivity and temperature for a concentration value and determining which of the predetermined polynomials corresponds to the relationship between the determined permittivity, the determined conductivity and the determined temperature.

4. The method of claim 1, including predetermining a plurality of relationships that are each indicative of a relationship between permittivity and conductivity for corresponding, predetermined concentration values and determining which of the predetermined relationships corresponds to the relationship between the determined permittivity and the determined conductivity.

5. The method of claim 4, including predetermining a plurality of polynomials that are each indicative of the plurality of relationships.

6. The method of claim 1, including providing a single capacitor, arranging the capacitor such that at least some of the fluid is between a cathode and an anode of the capacitor, and operating the capacitor at a first frequency for determining the permittivity and operating the capacitor at a second frequency for determining the conductivity.

7. The method of claim 1, wherein the component has a dielectric characteristic that is not constant and depends on a chemical reaction associated with the component.

8. The method of claim 7, wherein the component dielectric characteristic depends on a temperature of the fluid.

9. The method of claim 1, wherein the component is urea and the fluid includes water.

10. The method of claim 1, including determining if the fluid includes at least one contaminant.

11. The method of claim 10, including determining if the direct relationship corresponds to at least one expected relationship and determining that the fluid includes at least one contaminant when the direct relationship does not correspond to at least one expected relationship.

12. A sensor device for determining a concentration of a component within a fluid, comprising:
a capacitor having two electrodes that are adapted to be exposed to the fluid such that the fluid acts as a dielectric between the electrodes; and
a controller that determines a permittivity of the fluid based on the capacitor operating in a first mode and determines a conductivity of the fluid based on the capacitor operating in a second mode, the controller determines a direct relationship between the determined permittivity and the determined conductivity to obtain an indication of the concentration.

13. The sensor device of claim 12, including a plurality of oscillators that the controller selectively couples to the capacitor for operating the capacitor in the first and second modes, respectively.

14. The sensor device of claim 12, including a temperature sensor for detecting a temperature of the fluid and wherein the controller uses the determined permittivity, the determined conductivity and the detected temperature of the fluid to obtain the indication of the concentration.

15. The sensor device of claim 12, including a memory portion that includes a data set defining a plurality of relationships between at least the permittivity and the conductivity for a plurality of known concentrations, respectively.

16. The sensor device of claim 15, wherein the data set includes at least one three dimensional polynomial defining at least one relationship between permittivity, conductivity and temperature for at least one known concentration.

17. The sensor device of claim 15, wherein the data set indicates a range of expected relationships for a chosen range of concentrations and wherein the controller determines at least one of a contamination of the fluid or an undesirable concentration level when the relationship between the determined permittivity and the determined conductivity is not within the range of expected relationships.

18. The sensor device of claim 12, wherein the controller provides an output that indicates the concentration and a temperature of the fluid.

19. The sensor device of claim 18, wherein the controller output comprises a digital signal including a first pulse having a duration that is indicative of the temperature and a second pulse having a duration that is indicative of the concentration.

20. The sensor device of claim 12, wherein the controller determines if the fluid includes a contaminant by determining whether the direct relationship corresponds to at least one expected relationship.
